(19) United States
(12) Patent Application Publication
(10) Pub. No.: US 2024/0397613 A1
(43) Pub. Date: Nov. 28, 2024

(54) BREAKPOINT INSULATION FILM

(71) Applicant: Taicang Manaflex Technology Co., Ltd., Taicang City (CN)

(72) Inventors: Robert C. LANE, Las Vegas, NV (US); Yifei LIU, Toronto (CA); Shaodan XU, Suzhou (CN)

(21) Appl. No.: 18/672,197

(22) Filed: May 23, 2024

(30) Foreign Application Priority Data
May 24, 2023 (CN) 202321270100.7

(51) Int. Cl. H05K 1/02; H01M 50/519

(52) U.S. Cl. CPC H05K 1/0256; H01M 50/519; H05K 2201/05; H05K 2201/10037

(57) ABSTRACT

A breakpoint insulating film includes an insulating film body laminated on the surface of the flexible circuit. The insulating film has a main body that includes a battery connection area, and the battery connection area is provided with several electrode holes. The battery connection area is along the insulating film body. Several positioning hole groups are provided in the length direction, and the adjacent positioning holes include several breakpoint tearing line groups between the positioning hole groups. A split line group runs through the battery connection along the width direction of the insulating film body. The film has a simple structure and can be adjusted to a certain position through a tearing line group. The position of the positioning hole group improves the positioning between the insulating film and the flexible circuit.

### CROSS-REFERENCE TO RELATED APPLICATION

This application claims priority under 35 U.S.C. § 119 to Chinese Utility Model application No. 202321270100.7 filed on May 24, 2023, the disclosure of which is hereby incorporated by reference in its entirety for all purposes.

### FIELD OF INVENTION

The utility model relates to the technical field of new energy batteries, and in particular to a breakpoint insulating film.

### BACKGROUND

New energy vehicles refer to the use of unconventional vehicle fuels as power sources, including electric vehicles that use electricity storage. Ae battery pack provides a power source for the car. A battery pack includes a number of cylindrical batteries. Flexible circuit boards are used between the cylindrical batteries and other connections, and then the whole system is connected to the corresponding circuit through plugging or welding. The flexible circuit board includes connecting columns. Flexible circuits of shaped batteries and insulating films laminated on the surface of flexible circuits, etc. The insulating film avoids the soldering required for welding or plugging. Disk, positioning holes are processed on the insulating film and the flexible circuits are positioned and fixed, but the battery packs used in some electric vehicles are longer than two meters, and multiple sets of positioning holes are required for positioning. Due to problems such as processing accuracy, it is easy to cause deviations in the positioning of the positioning holes and other problems. Therefore, improvements need to be made.

### SUMMARY

A purpose of the disclosed breakpoint insulating film is to overcome the deficiencies in conventional films.

To achieve the above object, the present invention provides the following technical solutions:

The disclosure relates to a type of breakpoint insulating film, including:
An insulating film body that is laminated on the surface of a flexible circuit to protect the flexible circuit;
A battery connection area includes a number of electrode holes arranged in the insulating film body, which exposes the positive electrode of the flexible circuit. Positive connection points and negative connection points can be connected to the positive and negative terminals of a cylindrical battery;
Several positioning hole groups are provided along the length direction of the insulating film body;
Several tearing line groups are arranged between the adjacent positioning hole groups, and each tearing line group is arranged along the width direction of the insulating film body and runs through the battery connection area.

Further, in the above-mentioned breakpoint insulating film, the positioning hole group includes diagonally arranged circular positioning holes and oval-shaped positioning holes.

Further, in the above-mentioned breakpoint insulation film, the tear line group and the flexible circuit are staggered.

Further, in the above-mentioned breakpoint insulating film, the tear line group includes several breakpoint tear lines.

Further, in the above-mentioned breakpoint insulating film, the adjacent breakpoint tears in the same tear line group are formed by split lines that are connected through corresponding electrode holes.

Further, in the above-mentioned breakpoint insulating film, a plurality of avoidance holes are provided at both ends of the battery connection area. The breakpoint tearing lines at both ends of the tear line group respectively extend to the corresponding relief grooves.

Further, in the above-mentioned breakpoint insulating film, the breakpoint tear line includes a plurality of grooves arranged at intervals.

Advantages of the disclosed breakpoint insulation film include the film being a simple structure that is easily assembled and can be adjusted by one or more tearing lines. Adjusting the position of the positioning hole group to improve the positioning accuracy between the insulation film and the flexible circuit is another advantage.

### BRIEF DESCRIPTION OF THE DRAWINGS

In order to more clearly illustrate the embodiments of the present invention or the technical solutions in the prior art, the following examples or the drawings provided. Obviously, the drawings in the following description are only some possible embodiments. For those of ordinary skill in the art, without exerting creative efforts, other drawings can be contemplated and are within this disclosure.

FIG. 1 is a schematic structural diagram of a discontinuous point insulating film according to a specific embodiment of the present invention.

FIG. 2 shows a schematic structural diagram of the tear line group in a specific embodiment of the present invention.

FIG. 3 shows a structural schematic diagram of a breakpoint tear line according to a specific embodiment of the present invention.

### DETAILED DESCRIPTION

Below, in conjunction with the accompanying drawings in the embodiments of the present disclosure, the technical solutions in the embodiments of the present disclosure are carried out. This detailed description of the described embodiments are only part of the embodiments of the present invention, rather than all example implementations. Based on the embodiments of the present invention, those of ordinary skill in the art can make the all other obtained embodiments belong to the protection scope of the present disclosure.

In the description of the present utility model, it should be noted that the terms “center”, “upper”, “lower”, “left”, “right”, and “vertical”, as well as the orientations or positional relationships indicated by “straight”, “horizontal”, “inside”, “outside”, etc. are based on the orientations or positional relationships shown in the drawings and are only in order to facilitate the description of the present invention and simplify the description, it is not intended to indicate or imply that the device or element referred to must have a specific orientation, structure and operation in a specific orientation, therefore it cannot be construed as a limitation of the present invention. Furthermore, the term “section” and the terms “one”, “second”, and “third” are used for descriptive purposes only and are not to be construed as indicating or implying relative importance.

In this description, it should be noted that, unless otherwise clearly specified and limited, the terms “install” and “connect” should be understood in a broad sense. For example, they can refer to a fixed connection, a detachable connection, or an integral connection; as well as a mechanical connection or an electrical connection; and also a direct connection or an indirect connection through an intermediate medium. Alternatively, it can be an internal connection between two components. For those of ordinary skill in the art, the above terms can be understood in specific situations.

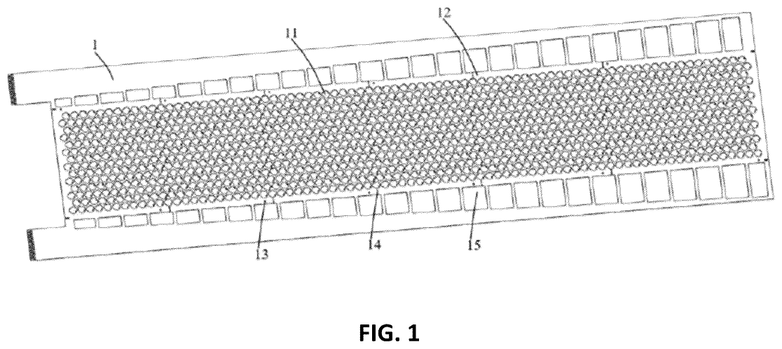

Illustratively, as shown in FIGS. 1 to 3, in one embodiment, a breakpoint insulating film includes the following features.

The insulating film body 1 is a sheet structure that is made of materials such as polyethylene terephthalate (PET) or ethylene glycol ester. The size and shape of the film body 1 are cut according to the wiring of the flexible circuit, and processed through common processes such as heat pressing. The standard process involves laminating the insulating film body 1 on the surface of the flexible circuit (not shown) to protect the flexible circuit. The surface of the flexible circuit is determined based on the actual characteristics of the battery pack.

The battery connection area of the insulative film body 1 includes a number of electrode holes 11 arranged in the insulating film body 1, exposing the positive electrode connections of the flexible circuit. Contact and negative electrode connection points to connect to the positive and negative electrodes of the cylindrical battery, the size and position of the electrode holes, etc. are determined according to the cylindrical battery and depend on the size and distribution of the positive electrode connections.

Several positioning hole groups are provided along the length direction of the insulating film body 1.

Several tear line groups are arranged between adjacent positioning hole groups, and the tear line group is along the insulating film body 1. The width direction runs through the battery connection area.

In this technical solution, the insulating film body is laminated on the flexible circuit, and the positioning hole group and the corresponding structure on the flexible circuit positioning, when there is a position deviation in the positioning hole group, the corresponding part of the tear line group will be torn at the same time to meet the positioning of the positioning hole group. As a result, the positioning accuracy between the insulation film body and the flexible circuit is improved.

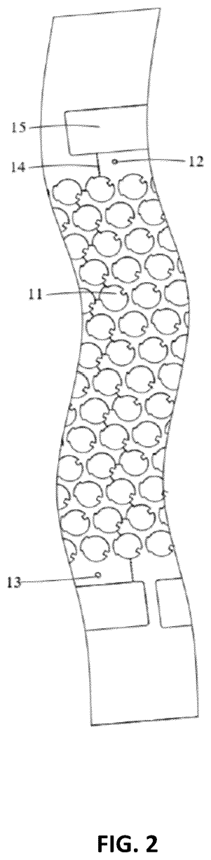

In one embodiment, exemplarily, as shown in FIGS. 1 and 2, the positioning hole group includes diagonally arranged circular positioning holes 12 and oval-shaped positioning holes 13.

In this technical solution, each pair of the circular positioning hole 12 and the oval-shaped positioning hole 13 are respectively located on both sides of the corresponding part of the battery connection area, and they are set diagonally from each other. The center line of the length direction of the oval-shaped positioning hole passes through the center of the circular positioning hole, that is, the oval-shaped positioning hole is at an absolute position. There is room for adjustment in both the length and width directions of the membrane body.

As illustrated, the tear line groups and the flexible lines are staggered.

In this technical solution, problems such as leakage caused by exposed flexible circuits are avoided.

Exemplarily, as shown in FIGS. 1 to 3, the tear line group includes a plurality of breakpoint tear lines 14.

In this technical solution, several breakpoint tear lines 14 can be provided in various forms such as straight lines, curves or broken lines. The distribution of breakpoint tear lines 14 is set according to the distribution of cylindrical batteries and flexible circuits to avoid exposing the flexible connections except the positive and negative connection points.

Illustratively, as shown in FIGS. 1 to 3, adjacent breakpoint tear lines 14 in the same tear line group pass through the corresponding electrode holes 11 to which the tear lines 14 are connected.

In this technical solution, the breakpoint tear lines in the same tear line group are in the form of broken lines as a whole, and pass through the adjacent break lines. The electrode holes between the point-type tear lines are connected to each other, so that the entire battery connection area is penetrated, reducing the number of notches and ensuring insulation. The strength of the membrane body can also adjust the position of the positioning hole group.

Illustratively, as shown in FIGS. 1 and 2, a number of escape grooves 15 are provided at both ends of the battery connection area. The breakpoint tearing lines 14 at both ends of the line group extend to corresponding escape grooves 15 respectively.

In this technical solution, the escape groove 15 is used to avoid the electrical components mounted on the flexible circuit board, etc., and the two ends of the tear line group 14 include breakpoint tear lines that are extend to the corresponding avoidance grooves 15, thereby expanding the range of the breakpoint tear lines 14 that can be adjusted.

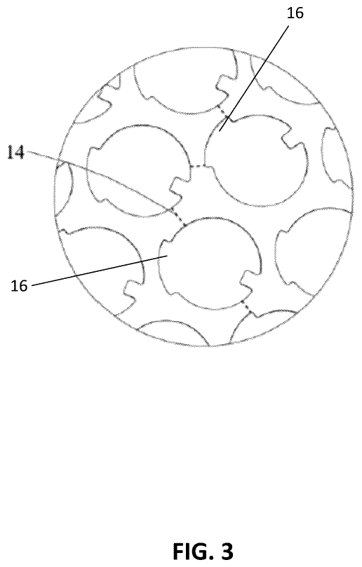

Exemplarily, as shown in FIG. 3, the breakpoint tear line 14 includes a plurality of notches 16 arranged at intervals.

In this technical solution, the breakpoint tear line 14 includes a plurality of notches 16 arranged at intervals, and the breakpoint tear line 14 can be manually torn along the breakpoint. Corresponding parts of the insulation film body can be torn apart for easy operation. The connection points between the notches can be torn off, and stretched and deformed. When the group offset size is small, pulling the insulation film body at both ends of the breakpoint tear line can meet the adjustment needs, and the positioning hole group offset. When the transfer size is large, the insulation film body can be torn along the breakpoint tear line to meet the adjustment needs, depending on the circular positioning holes and/or oval-shaped positioning holes. When the positioning position is offset, the insulation film body can be torn off at the corresponding end along the breakpoint tear line.

In summary, the disclosed film has a simple structure, and the heating device can automatically limit the temperature and improve the safety of use. There is no need to set up a separate temperature control circuit, which facilitates a thin and light design and does not take up space.

It should be noted as used herein, the terms “include” or “including” and any variation thereof are intended to be non-exclusive and include additional elements, such that a process, method, article or equipment that includes a series of elements not only includes those elements, but and also includes other elements not expressly listed or inherent in such process, method, article or equipment elements. Without further limitation, elements qualified by the statement “includes a” are not excluded from inclusion of additional elements. There are other identical elements in the process, method, article or equipment that describe the elements mentioned above.

The above is only one implementation of a film according to the present invention. It should be understood that for one of ordinary skill in this technical field and in the related art, several improvements and modifications can be made without departing from the principles of the present invention. These improvements should be considered as included in the scope of this disclosure.

What is claimed is:

1. A breakpoint insulation film, comprising:
an insulation film body that is laminated on a surface of a flexible circuit to protect the flexible circuit, the insulation film body including:
a battery connection area that includes electrode holes provided in the insulation film body, the electrode holes exposing a positive connection of a flexible circuit and negative terminal connection points to connect positive and negative terminals of a battery;
positioning hole groups provided along a length direction of the insulation film body; and
tearing line groups arranged between adjacent ones of the positioning hole groups, the tearing line groups are arranged along a length the insulation film body, and a width direction of the insulation film body runs through the battery connection area.

2. The breakpoint insulation film according to claim 1, wherein each of the positioning hole groups includes diagonally arranged circles, which include a circular positioning hole and an oval-shaped positioning hole.

3. The breakpoint insulation film according to claim 1, wherein the tear line groups are staggered along the length of the insulation film body.

4. The breakpoint insulation film according to claim 1, wherein each tear line group includes a plurality of breakpoint tear lines.

5. The breakpoint insulation film according to claim 4, wherein the plurality of breakpoint tear lines in a tear line group are connected through corresponding electrode holes.

6. The breakpoint insulation film according to claim 4, wherein two ends of the battery connection area are respectively provided with escape grooves, and the breakpoint tear lines at both ends of a tear line group extend to the corresponding escape grooves.

7. The breakpoint insulation film according to claim 4, wherein the breakpoint tear line includes a plurality of grooves formed in the insulation film body at several intervals.
